(19) United States
(12) Patent Application Publication
(10) Pub. No.: US 2011/0147804 A1
(43) Pub. Date: Jun. 23, 2011

(54) Drive current enhancement in tri-gate MOSFETS by introduction of compressive metal gate stress using ion implantation

(76) Inventors: Rishabh Mehandru, Beaverton, OR (US); Cory E. Weber, Hillsboro, OR (US); Ashutosh Ashutosh, Hillsboro, OR (US); Jack Hwang, Portland, OR (US)

(21) Appl. No.: 12/646,673

(22) Filed: Dec. 23, 2009

(51) Int. Cl. H01L 29/78; H01L 21/20

(52) U.S. Cl. 257/255; 438/478; 438/659; 257/E21.09; 257/E29.255

(57) ABSTRACT

A semiconductor device comprises a fin and a metal gate film. The fin is formed on a surface of a semiconductor material. The metal gate film formed on the fin and comprises ions implanted in the metal gate film to form a compressive stress within the metal gate. In one exemplary embodiment, the surface of the semiconductor material comprises a (100) crystalline lattice orientation, and an orientation of the fin is along a <100> direction with respect to the crystalline lattice of the semiconductor. In another exemplary embodiment, the surface of the semiconductor material comprises a (100) crystalline lattice orientation, and the orientation of the fin is along a <110> direction with respect to the crystalline lattice of the semiconductor. The fin comprises an out-of-plane compression that is generated by the compressive stress within the metal gate film.

### BACKGROUND

Carbon-doped silicon epitaxial layers are deposited on source and drain areas of Tri-gate transistors to generate a tensile stress in the channel of transistor to enhance the carrier mobility and the drive current of the channel. This technique, though, only provides a relatively low carrier mobility and, consequently, has a relatively low saturated drain current Idsat and linear drain current Idlin.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 depicts a flow diagram for one exemplary embodiment of a process of using ion implantation to form compressive metal-gate stress in a Tri-gate NMOS transistors to generate out-of-plane compression in the channel of the transistor according to the subject matter disclosed herein;

FIGS. 2A and 2B depict cross-section views of a portion of an exemplary embodiment of a Tri-gate transistor during a process according to the subject matter disclosed herein;

FIG. 3 depicts a perspective view of a portion of an NMOS Trig-gate transistor illustratively providing simulated out-of-plane compressive force stress levels that are generated on the channel of the transistor by ion implantation into the gate of the transistor;

FIG. 4 shows a graph illustratively depicting long-channel (LC) mobility gain as a function of stress measured in MPa; and

FIGS. 5 and 6 respectively illustratively show simulation results for Idsat and Idlin for a device with a <110> channel orientation and a (100) top surface orientation without metal gate stress.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments are described herein for enhancing drive current in Tri-gate MOSFETS by using Ion implantation to create compressive metal gate stress. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments. The word “exemplary” is used herein to mean “serving as an example, instance, or illustration.” Any embodiment described herein as “exemplary” is not to be construed as necessarily preferred or advantageous over other embodiments.

The subject matter disclosed herein provides a technique for further enhancing the carrier mobility and drive current by forming compressive metal gate stress by implantation of ions into the metal gate to generate out-of-plane compression in the channel of the transistor.

As critical dimensions of transistors become increasingly smaller with each new generation of transistors, the process for gate metal deposition tends to be a chemical vapor deposition (CVD) process, such as an atomic layer deposition (ALD) process, as opposed to sputtering in order to avoid formation of voids in the gate metal. It is known that such ALD-deposited metals have an intrinsic tensile strain instead of a compressive strain that is normally seen in connection with sputtered materials. The subject matter disclosed herein forms a compressive stress in an ALD-deposited gate metal layer by implanting ions, such as, but not limited to, nitrogen, xenon, argon, neon, krypton, radon, ef-carbon, aluminum or titanium, or combinations thereof, in the metal gate.

The subject matter disclosed herein relates to using ion implantation to form compressive metal-gate stress in Tri-gate, or finFET, NMOS transistors and to thereby generate out-of-plane compression in the channel of the transistor, which enhances carrier mobility and drive current of the channel. The compressive gate strain formed by the ion implantation transfers to the channel as compressive strain end of line for the dominate sidewall transistor of the Tri-gate transistor. According to one exemplary embodiment, carrier mobility and drive current are significantly enhanced by exerting out-of-plane compression on a channel that is oriented in the <110> direction that is formed on a wafer having a top surface (110) crystalline lattice, in which the sidewall of the channel has a (100) crystalline lattice orientation. Similar carrier mobility and drive current enhancement from out-of-plane compression is also exhibited for a channel oriented in a <100> direction that is formed on a wafer having a top surface (100) crystalline lattice, in which the sidewall of the channel has a (100) orientation.

According to the subject matter disclosed herein, ions are implanted in the metal gate of a Tri-gate NMOS transistor to generate compressive stress in a channel that is oriented in the <110> direction and is formed on the top surface of a wafer having a (100) crystalline lattice orientation. Alternatively, compressive stress can be generated in a channel by ion implantation into the metal gate of a Tri-gate transistor such that the channel is oriented in the <100> direction that has been formed on the top surface of a wafer having a (100) crystalline lattice orientation. The techniques of the subject matter disclosed herein may be less complicated that conventional EPI growth techniques that form channel strain, which requires multiple steps. Additionally, as the pitch and gate scales, EPI regions used by conventional techniques shrink much faster than gate (or channel length Lg), which makes the techniques disclosed herein attractive at narrower pitches.

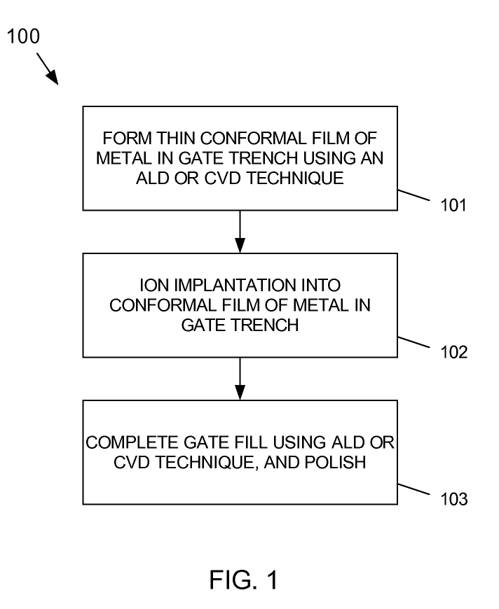

FIG. 1 depicts a flow diagram for one exemplary embodiment of a process 100 of using ion implantation to form compressive metal-gate stress in a Tri-gate NMOS transistors to generate out-of-plane compression in the channel of the transistor according to the subject matter disclosed herein. The exemplary embodiment depicted in FIG. 1, comprises two stages in which during the first stage, a thin conformal film of metal having a thickness of between about 2 nm and about 100 nm is deposited, as depicted by step 101. In one exemplary embodiment, the thickness of the thin conformal film is about 10 nm. Suitable metals that could be used for the thin conformal film of metal include, but are not limited to, aluminum, barium, chromium, cobalt, hafnium, iridium, iron, lanthanum and other lanthanides, molybdenum, niobium, osmium, palladium, platinum, rhenium, ruthenium, rhodium, scandium, strontium, tantalum, titanium, tungsten, vanadium, yttrium, zinc, or zirconium, or combinations thereof. At step 102, ions, such as, but not limited to aluminum, barium, chromium, cobalt, hafnium, iridium, iron, lanthanum and other lanthanides, molybdenum, niobium, osmium, palladium, platinum, rhenium, ruthenium, rhodium, scandium, strontium, tantalum, titanium, tungsten, vanadium, yttrium, zinc, zirconium, nitrogen, xenon, argon, neon, krypton, radon, or carbon, or combinations thereof, are implanted into the gate metal using a well-known ion implantation technique. Implantation dose can be between about 1×10¹⁵/cm² and about 1×10′⁷/cm², and implantation energy could vary between about 0.1 keV and about 500 keV.

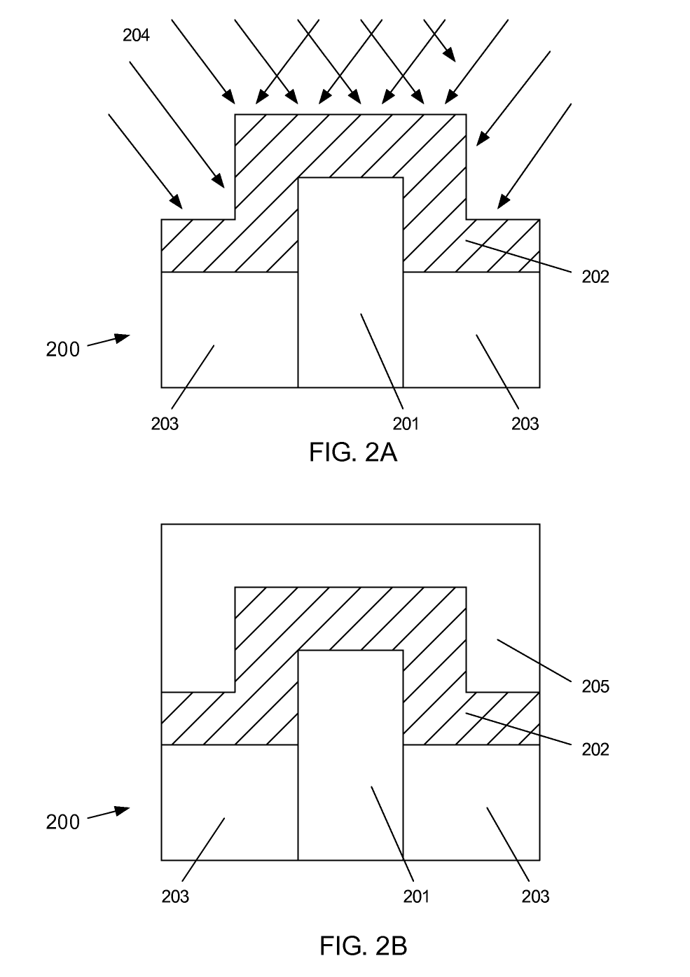

FIG. 2A depicts a cross-section view of a portion of an exemplary embodiment of a

Tri-gate transistor 200 in which fin 201 and gate metal film 202 are shown. Fin 201 is disposed between oxides 203. As depicted in FIG. 2A, in the first stage, gate metal film 202 is deposited to form a thin conformal film of metal using an atomic layer deposition (ALD) or a chemical vapor deposition (CVD) deposition technique (step 101). During step 102 in FIG. 1, ions 104, such as, but not limited to, aluminum, barium, chromium, cobalt, hathium, iridium, iron, lanthanum and other lanthanides, molybdenum, niobium, osmium, palladium, platinum, rhenium, ruthenium, rhodium, scandium, strontium, tantalum, titanium, tungsten, vanadium, yttrium, zinc, zirconium, nitrogen, xenon, argon, neon, krypton, radon, or carbon, or combinations thereof, are implanted into gate metal film 202 using a well-known ion implantation technique. It should be understood that almost any ion from the periodic table of elements could be implanted into gate metal film 202. Additionally, it should be understood that lighter-weight ions might be function as contaminants and, therefore, be less preferred than other ions.

During the second stage of the process after the ion implantation step 102, flow continues to step 103 where the gate fill 205, such as a low-resistance metal, is completed by using a well-known ALD process and followed by polishing. FIG. 2B depicts transistor 200 after step 103. In one exemplary embodiment, a nitrogen ion implantation dose of about 1.2×10¹⁶ at an implantation angle of about 45° achieves about a 1% compressive strain in the gate metal.

In another exemplary embodiment, the ion implantation of step 103 could be done after the gate fill and polish of step 104.

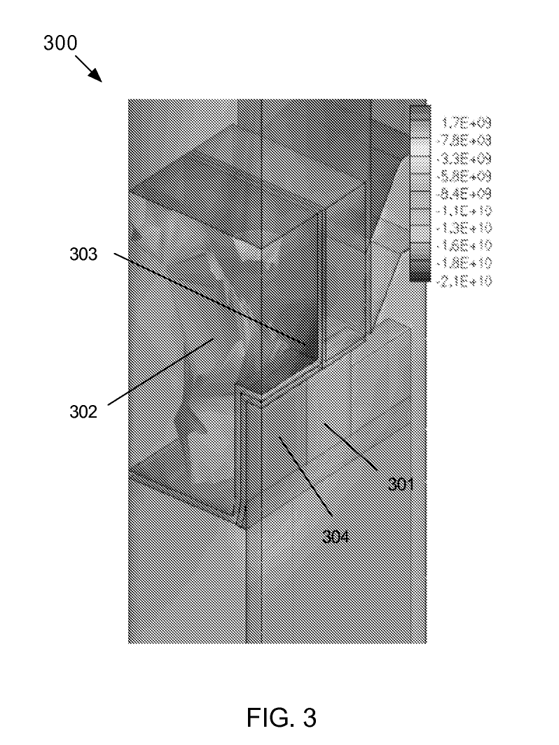

FIGS. 3-6 depict results of tests and/or simulations, and are provided only for illustrative purposes and should not be construed or interpreted as limitations or expectations of the subject matter disclosed herein. FIG. 3 depicts a perspective view of a portion of an NMOS Trig-gate transistor 300 providing illustrative simulated out-of-plane compressive force stress levels that are generated on the channel of the transistor by ion implantation into the gate of the transistor. More specifically, FIG. 3 more specifically depicts a channel 301 and a gate 302 in which nitrogen ions have been implanted (simulated). The shade of gray represents a level of out-of-plane stress measured in dynes/cm². A range of the compressive forces depicted in FIG. 3 is shown in the upper right of FIG. 3. As depicted in FIG. 3, when a compressive stress of about 2.1×10¹⁰ dynes/cm² is formed in gate 302 at 303, an out-of-plane compressive force of about 8.4×10⁹ dynes/cm² is generated in channel 301 at 304.

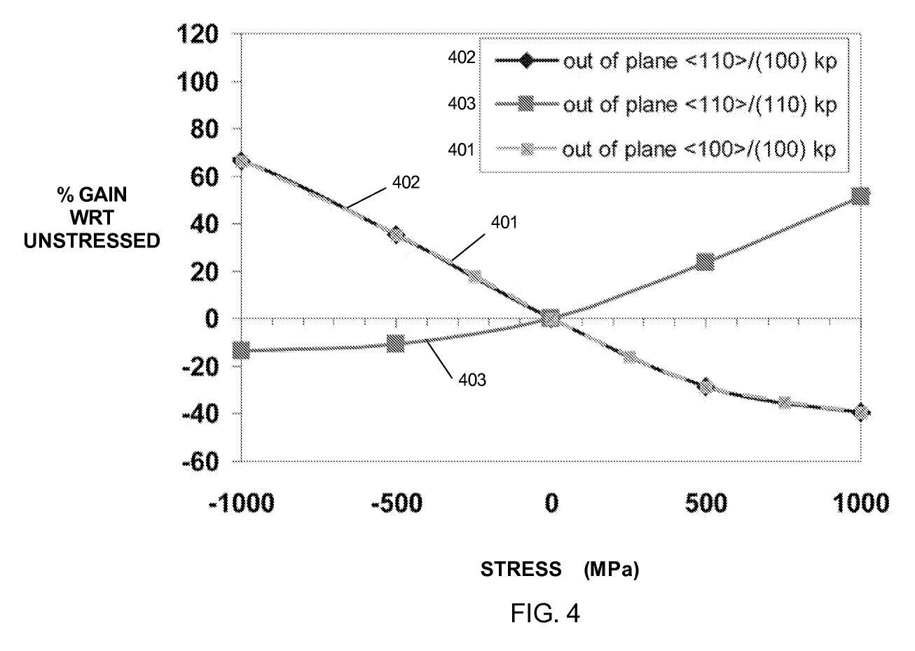

FIG. 4 shows a graph illustratively depicting long-channel (LC) mobility gain as a function of stress measured in MPa. As can be seen in FIG. 4, out-of-plane compression provides carrier mobility and drive current enhancement for (100) wafer orientations with either <110> or <100> channel orientations, but does not provide carrier mobility and drive current enhancement for (110) wafer orientation with a <110> channel orientation. Curves 401 and 402 are superimposed on each other and respectively represent the mobility gain for a (100) wafer orientation with a <110> channel orientation, and a (100) wafer orientation with a <100> channel orientation. Curve 403 is the mobility gain for a (110) wafer orientation with a <110> channel orientation. Thus, for an NMOS Tri-gate transistor, a (110) top wafer orientation with a <110> channel orientation provides a beneficial (100) orientation for the sidewall transistor.

According to the subject matter disclosed herein, a similar benefit for long-channel devices is also seen for a <100> channel orientation on (100) top wafer, which also has a <100> oriented channel on (100) sidewall. If either a (110) top surface with a <110> channel orientation or a (100) top surface with a <100> channel orientation is used, about a 37% Idsat gain and about a 17% Idlin gain was observed in simulations.

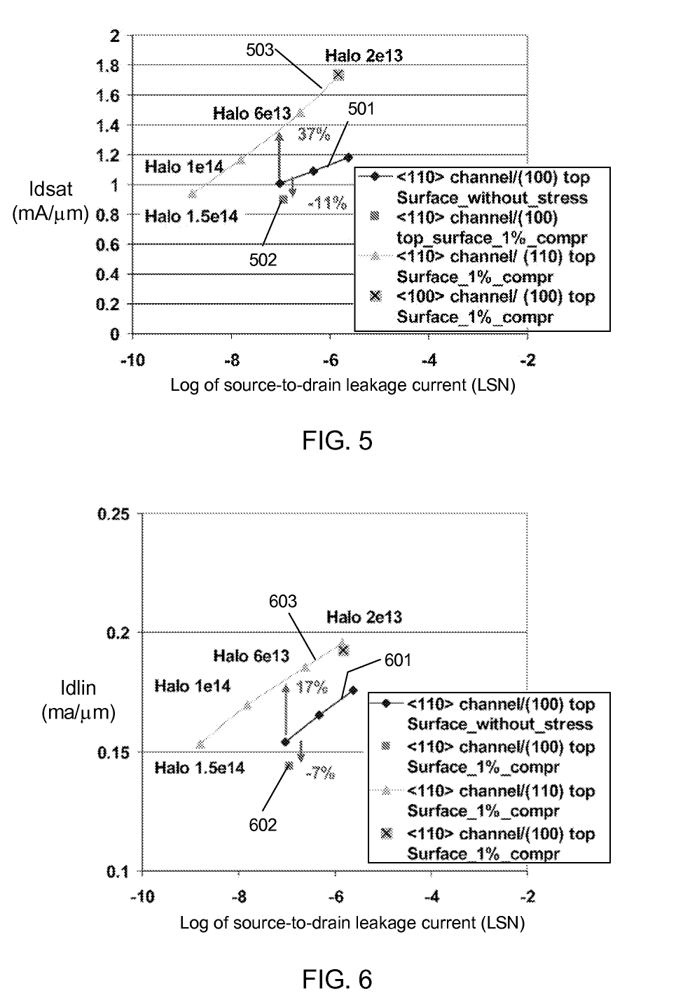

FIGS. 5 and 6 respectively illustratively show simulation results for Idsat and Idlin for device with a <110> channel orientation and a (100) top surface orientation without metal gate stress. In FIGS. 5 and 6, the abscissa is the log of the source-to-drain leakage current in A/μm, and the ordinate is measured in mA/μm. The “HALO” designations in FIGS. 5 and 6 refer to doping implants in number of ions/cm². Baselines for FIGS. 5 and 6 are respectively curves 501 and 601. On addition of metal gate stress, but no surface orientation change, there is a reduction in drives of about 11% Idsat (shown at 502) and about 7% Idlin (shown at 602). With a compressive metal gate stress and a surface orientation change to be a (110) top surface, there is about a 37% Idsat gain (shown at 503) and about a 17% Idlin gain at matched Ioff (shown at 603). A similar gain is also observed when metal gate stress is combined with a <100> channel orientation, but the top surface is kept the same as (100).

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined by the following claims, which are to be construed in accordance with established doctrines of claim interpretation.

What is claimed is:

1. A method for making a semiconductor device, the method comprising:
forming a fin of the semiconductor device on a surface of a semiconductor material;
forming a metal gate film for the semiconductor device on the fin; and
implanting ions in the metal gate film.

2. The method according to claim 1, wherein the surface of the semiconductor material comprises a (100) crystalline lattice orientation, and an orientation of the fin is along a <100> direction with respect to the crystalline lattice of the semiconductor, or the surface of the semiconductor material comprises a (100) crystalline lattice orientation, and the orientation of the fin is along a <110> direction with respect to the crystalline lattice of the semiconductor.

3. The method according to claim 2, wherein forming the metal gate film on the fin comprises forming a conformal metal film in a gate trench of the gate; and
wherein implanting ions in the metal gate film comprises implanting ions in the conformal metal film, and
the method further comprising completing a gate fill on the ion-implanted conformal metal film in the gate trench of the gate.

4. The method according to claim 3, wherein implanting ions in the metal gate film further comprises implanting ions at a dosage of between about 1×10¹⁵ ions/cm² and about 1×10¹⁷ ions/cm², and at an implantation energy of between about 0.1 keV and about 500 keV.

5. The method according to claim 4, wherein the conformal metal film comprises aluminum, barium, chromium, cobalt, hafnium, iridium, iron, lanthanum and other lanthanides, molybdenum, niobium, osmium, palladium, platinum, rhenium, ruthenium, rhodium, scandium, strontium, tantalum, titanium, tungsten, vanadium, yttrium, zinc, or zirconium, or combinations thereof.

6. The method according to claim 5, wherein the ions comprise nitrogen, xenon, argon, neon, krypton, radon, carbon, aluminum, or titanium, or combinations thereof.

7. The method according to claim 6, wherein the semiconductor device comprises a finFET device.

8. The method according to claim 7, wherein forming the conformal metal film comprises forming the conformal metal film using an atomic layer deposition technique or a chemical vapor deposition technique.

9. The method according to claim 3, wherein completing the gate fill on the ion-implanted conformal metal film comprises completing the gate fill using an atomic layer deposition technique or a chemical vapor deposition technique.

10. The method according to claim 9, wherein the ions comprise nitrogen, xenon, argon, neon, krypton, radon, carbon, aluminum, or titanium, or combinations thereof.

11. The method according to claim 10, wherein implanting ions in the metal gate film further comprises implanting ions at a dosage of between about 1×10¹⁵ ions/cm² and about 1×10¹⁷ ions/cm², and at an implantation energy of between about 0.1 keV and about 500 keV.

12. The method according to claim 11, wherein the conformal metal film comprises aluminum, barium, chromium, cobalt, hafnium, iridium, iron, lanthanum and other lanthanides, molybdenum, niobium, osmium, palladium, platinum, rhenium, ruthenium, rhodium, scandium, strontium, tantalum, titanium, tungsten, vanadium, yttrium, zinc, or zirconium, or combinations thereof.

13. The method according to claim 12, wherein the semiconductor device comprises a finFET device.

14. A semiconductor device, comprising:
a fin formed on a surface of a semiconductor material; and
a metal gate film formed on the fin, the metal gate film comprising ions implanted in the metal gate.

15. The semiconductor device according to claim 14, wherein the surface of the semiconductor material comprises a (100) crystalline lattice orientation, and an orientation of the fin is along a <100> direction with respect to the crystalline lattice of the semiconductor, or the surface of the semiconductor material comprises a (100) crystalline lattice orientation, and the orientation of the fin is along a <110> direction with respect to the crystalline lattice of the semiconductor, and wherein the fin comprises an out-of-plane compression generated by the compressive stress within the metal gate.

16. The semiconductor device according to claim 15, wherein the metal gate film comprises:
a conformal metal film formed in a gate trench of the gate, the implanted ions being implanted in the conformal metal film; and
a gate fill formed on the ion-implanted conformal metal film in the gate trench of the gate.

17. The semiconductor device according to claim 16, wherein the ions are implanted at a dosage of between about1×10¹⁵ ions/cm² and about 1×10¹⁷ ions/cm², and at an implantation energy of between about 0.1 keV and about 500 keV.

18. The semiconductor device according to claim 17, wherein the conformal metal film comprises aluminum, barium, chromium, cobalt, hafnium, iridium, iron, lanthanum and other lanthanides, molybdenum, niobium, osmium, palladium, platinum, rhenium, ruthenium, rhodium, scandium, strontium, tantalum, titanium, tungsten, vanadium, yttrium, zinc, or zirconium, or combinations thereof.

19. The semiconductor device according to claim 18, wherein the ions comprise nitrogen, xenon, argon, neon, krypton, radon, carbon, aluminum, or titanium, or combinations thereof

20. The semiconductor device according to claim 19, wherein the semiconductor device comprises a finFET device.

21. The semiconductor device according to claim 20, wherein forming the conformal metal film is formed by an atomic layer deposition technique or a chemical vapor deposition technique.

22. The semiconductor device according to claim 15, wherein the ions comprise nitrogen, xenon, argon, carbon, aluminum, or titanium, or combinations thereof.

23. The semiconductor device according to claim 22, wherein the ions are implanted at a dosage of between about 1×10¹⁵ ions/cm² and about 1×10¹⁷ ions/cm², and at an implantation energy of between about 0.1 keV and about 500 keV.

24. The semiconductor device according to claim 23, wherein the conformal metal film comprises aluminum, barium, chromium, cobalt, hafnium, iridium, iron, lanthanum and other lanthanides, molybdenum, niobium, osmium, palladium, platinum, rhenium, ruthenium, rhodium, scandium, strontium, tantalum, titanium, tungsten, vanadium, yttrium, zinc, or zirconium, or combinations thereof.

25. The semiconductor device according to claim 24, wherein the semiconductor device comprises a finFET device.
